(19) United States
(12) Patent Application Publication
(10) Pub. No.: US 2025/0267892 A1
(43) Pub. Date: Aug. 21, 2025

(54) Semiconductor device and forming method thereof

(71) Applicant: UNITED MICROELECTRONICS CORP., Hsin-Chu City (TW)

(72) Inventors: HUAN XU, Singapore (SG); Purakh Raj Verma, Singapore (SG); Shen-De Wang, Hsinchu County (TW); Chih-Chien Chang, Hsinchu City (TW); Cheng-Hua Yang, Singapore (SG)

(73) Assignee: UNITED MICROELECTRONICS CORP., Hsin-Chu City (TW)

(21) Appl. No.: 18/602,058

(22) Filed: Mar. 12, 2024

(30) Foreign Application Priority Data
Feb. 15, 2024 (TW) 113105221

(51) Int. Cl. H01L 29/78; H01L 29/06; H01L 29/40; H01L 29/66

(52) U.S. Cl. CPC H10D 30/65; H10D 30/0221; H10D 30/0281; H10D 30/603; H10D 62/127; H10D 64/111

(57) ABSTRACT

The invention provides a semiconductor device, which comprises a substrate, a first oxide layer located on a surface of the substrate, a gate electrode located on the substrate and partially contacting the substrate, and a field plate located on the first oxide layer, wherein the field plate has at least a rectangular frame shape when viewed from a top view.

### BACKGROUND OF THE INVENTION

### 1. Field of the Invention

The invention relates to a high voltage metal-oxide-semiconductor (hereinafter referred to as HV MOS) transistor device, in particular to a high voltage lateral double-diffused metal-oxide-semiconductor (HV-LDMOS) transistor device with a special shape.

### 2. Description of the Prior Art

Double-diffused MOS (DMOS) transistor devices have been paid more and more attention among power devices with high voltage processing capability. Common DMOS transistor devices include vertical double-diffused MOS (VDMOS) and lateral double-diffused MOS (LDMOS) transistor devices. LDMOS transistor devices have been widely used in high-voltage operating environment, such as CPU power supply, power management system, AC/DC converter, high-power or high-frequency power amplifier, etc., because of their high operating bandwidth and operating efficiency, and the planar structure that is easy to integrate with other integrated circuits. The LDMOS transistor device is mainly characterized by a low doping concentration and a large lateral diffusion drift region at the source terminal, which aims to alleviate the high voltage between the source terminal and the drain terminal, so that the LDMOS transistor device can obtain a higher breakdown voltage.

Because the two main characteristics pursued by HV MOS transistor devices are low on-resistance and high breakdown voltage, and these two requirements are often conflicting and difficult to weigh. Therefore, there is still a need for a solution that can operate normally in high voltage environment and meet the requirements of low on-resistance and high breakdown voltage at the same time. In addition, the electrostatic discharge (ESD) of HV MOS transistor devices will also affect the overall performance, so reducing the ESD of HV MOS transistor devices is also an important issue.

### SUMMARY OF THE INVENTION

The invention provides a semiconductor device, which comprises a substrate, a first oxide layer located on a surface of the substrate, a gate electrode located on the substrate and partially contacting the substrate, and part of the gate electrode located on the first oxide layer, and a field plate located on the first oxide layer, wherein the field plate has at least a rectangular frame shape when viewed from a top view.

The invention also provides a method for forming a semiconductor device, which comprises providing a substrate, forming a first oxide layer on a surface of the substrate, forming a gate electrode on the substrate, the gate electrode partially contacts the substrate, and part of the gate electrode located on the first oxide layer, and forming a field plate on the first oxide layer, wherein the field plate has at least a rectangular frame shape when viewed from a top view.

The invention is characterized by providing a semiconductor device with a filed plate, in particular to a lateral double-diffused metal-oxide-semiconductor (LDMOS) transistor device with a field plate with a special shape. In which, from the top view, the field plate presents a long rectangular frame shape or a net shape, while from the cross-sectional view, the field plate directly contacts the first oxide layer. The semiconductor device of the invention not only has the effect of dispersing electric field, but also has the advantages of simple process and stable structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic cross-sectional structure of a semiconductor device according to a first embodiment of the present invention.

FIG. 2 is a schematic cross-sectional view of a semiconductor device according to a second embodiment of the present invention.

FIG. 3 is a schematic top view of a field plate according to a second embodiment of the present invention.

FIG. 4 is a schematic cross-sectional view of a semiconductor device according to a third embodiment of the present invention.

FIG. 5 and FIG. 6 are schematic top views of two different embodiments of the field plate of the present invention, respectively.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

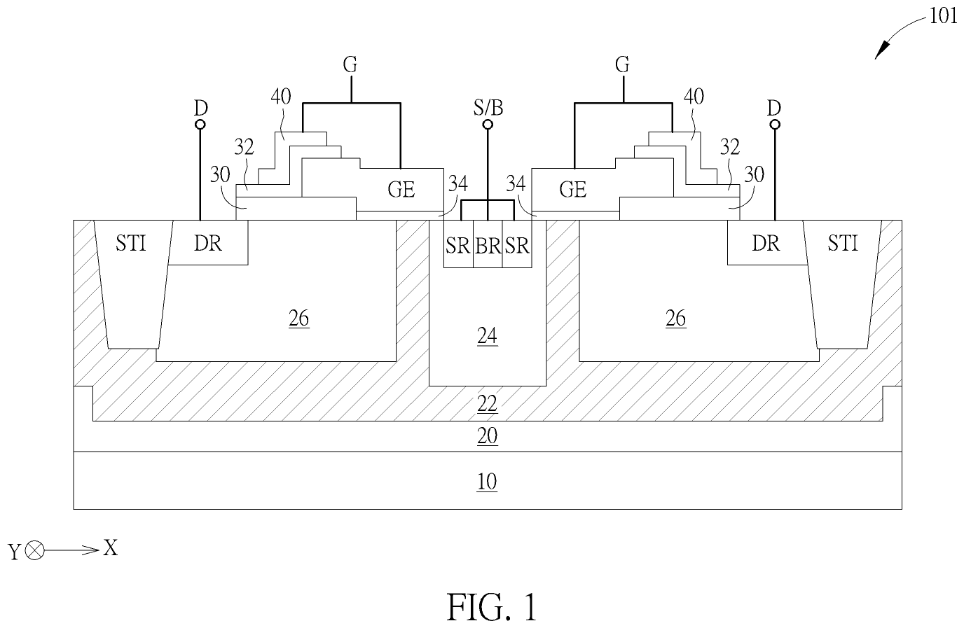

Please refer to FIG. 1. FIG. 1 shows a schematic cross-sectional structure of a semiconductor device according to a first embodiment of the present invention. As shown in FIG. 1, this embodiment provides a semiconductor device 101, and the semiconductor device 101 includes a substrate 10. The substrate 10 contains a source doped region SR, a drain doped region DR and a gate electrode GE in or on the substrate 10, which are respectively connected with a source terminal S, a drain terminal D and a gate terminal G, so as to form the smallest cell of a lateral double diffused metal-oxide-semiconductor (LDMOS) transistor. The semiconductor device 101 shown in FIG. 1 includes two minimum cells of LDMOS transistors, wherein the two cells are symmetrically arranged and share the source terminal S. The details will be described in the following paragraphs. In the following paragraphs, for the convenience of explanation, the smallest cell of one LDMOS transistor will be described. However, it is worth noting that although the semiconductor device 101 in FIG. 1 includes the smallest cell of two LDMOS transistors, the scope of the present invention also includes the smallest cell of one single LDMOS transistor. In other words, if other embodiments only include the smallest cell of an LDMOS transistor composed of a source doped region SR, a drain doped region DR and a gate electrode GE, this structure also belongs to one embodiment of the present invention.

Referring to FIG. 1, the substrate 10 at least includes a deep well region 20, a deep well region 22, a doped well region 24, a drift region 26 and a shallow trench isolation STI. The shallow trench isolation STI may be partially disposed in the substrate 10 to define a plurality of active area (not labeled in FIG. 1) in the substrate 10, and the shallow trench isolation STI may include a single layer or multiple layers of insulating materials such as oxide insulating materials (such as silicon oxide) or other suitable insulating materials.

The deep well region 20, the deep well region 22, the doped well region 24 and the drift region 26 may be disposed in the substrate 10 and may be doped regions formed in the substrate 10 by a doping process (such as an implantation process). The deep well region 22 may be located above the deep well region 20, the doped well region 24 is surrounded by the deep well region 22, and the drift region 26 may be located above the deep well region 22. In some embodiments, the deep well region 22 and the doped well region 24 may have a first conductivity type, while the deep well region 20 and the drift region 26 may have a second conductivity type, wherein the first conductivity type is complementary to the second conductivity type. For this embodiment, when the substrate 10 is a P-type semiconductor substrate or a substrate with a P-type doped region, the deep well region 20 can be an N-type doped deep well region, the deep well region 22 can be a P-type doped deep well region, the doped well region 24 can be a P-type doped well region, and the drift region 26 can be an N-type doped region, but it is not limited thereto. In some embodiments, an N-type substrate 10 or a substrate 10 with an N-type doped region can also be used according to design requirements, and the conductivity types of the above-mentioned well regions and doped regions can be adjusted accordingly.

In addition, the semiconductor device 101 may further include a body doping region BR. The body doped region BR and the source doped region SR may be disposed in the doped well region 24, and the drain doped region DR may be disposed in the drift region 26. The source doped region SR, the drain doped region DR, and the body doped region BR may be doped regions formed in the substrate 10 by a doping process (such as an implantation process), respectively. For example, the source doped region SR and the drain doped region DR may be heavily doped regions with the same conductivity type as the drift region 26 (for example, heavily N-type doped regions), and the body doped region BR may be heavily doped regions with the same conductivity type as the doped well region 24 (for example, heavily P-type doped regions), but it is not limited thereto. In some embodiments, the body doped region BR can be used to adjust the potential of the doped well region 24 and connected to a body terminal B. The body doped region BR and the source doped region SR can be regarded as the source doped region in the semiconductor device 101. From FIG. 1, the body doped region BR is connected to the source doped region SR, so they are equipotential, and FIG. 1 shows that the body terminal B and the source terminal S are connected to the body doped region BR, which also means that the body terminal B and the source terminal S are connected to the source doped region SR.

Referring to FIG. 1, the semiconductor device 101 further includes a gate electrode GE, a source doped region SR, a drain doped region DR, a first oxide layer 30, a second oxide layer 32, a gate dielectric layer 34 and a field plate 40. The gate electrode GE is disposed on the substrate 10. The source doped region SR and the drain doped region DR are disposed in the substrate 10 and located on two opposite sides of the gate electrode GE in a horizontal direction (such as the X direction in FIG. 1). The first oxide layer 30 is disposed on the drift region 26 and part of the drain doped region DR of the substrate 10, in which part of the gate electrode GE is located on the drift region 26 and directly contacts the gate dielectric layer 34, while the other part of the gate electrode GE covers the first oxide layer 30, that is, part of the gate electrode GE covers the sidewall and part of the top surface of the first oxide layer 30.

As shown in FIG. 1, a part of the second oxide layer 32 is located on the first oxide layer 30, and the other part of the second oxide layer 32 covers the gate electrode GE, that is, in this embodiment, the second oxide layer 32 covers the top surface of the first oxide layer 30, the sidewall of the gate electrode GE and part of the top surface of the gate electrode GE. The field plate 40 is partially disposed on the second oxide layer 32. With the arrangement of the first oxide layer 30, the second oxide layer 32 and the field plate 40, the on-resistance (Ron) of the semiconductor device 101 can be reduced or the electric field distribution can be adjusted, thereby improving the electrical performance of the semiconductor device 101.

In some embodiments, the substrate 10 may include a silicon substrate, an epitaxial silicon substrate, a silicon germanium substrate, a silicon carbide substrate, a silicon-on-insulator (SOI) substrate or a semiconductor substrate formed of other suitable semiconductor materials and/or structures. The first oxide layer 30 and the second oxide layer 32 may respectively comprise silicon oxide or other suitable oxide materials, and the material composition of the first oxide layer 30 may be the same as that of the second oxide layer 32, but it is not limited thereto. In some embodiments, the first oxide layer 30 and the second oxide layer 32 with different material compositions can also be used according to actual requirements. The gate electrode GE may include a nonmetallic conductive material (e.g., doped polysilicon) or a metallic conductive material, such as a metal gate electrode stacked by a work function layer and a low resistance layer, and the field plate 40 may include a nonmetallic conductive material (e.g., doped polysilicon) or a metallic conductive material. Therefore, in some embodiments, the material composition of the field plate 40 can be the same as that of the gate electrode GE, thereby simplifying the process steps (for example, when both the field plate 40 and the gate electrode GE are formed of polysilicon, a required silicide layer can be formed on the polysilicon together, but not limited thereto). However, in some embodiments, the field plate 40 and the gate electrode GE with different material compositions can also be used according to actual requirements.

In some embodiments, the semiconductor device 101 may further include a gate dielectric layer 34 and spacers (not shown), wherein the gate dielectric layer 34 may be disposed between the gate electrode GE and the substrate 10, and the spacers may be disposed on the sidewalls of the gate electrode GE. The gate dielectric layer 34 may include an oxide (e.g., silicon oxide), a high-k dielectric material, or other suitable dielectric materials. The high-k dielectric material may include hafnium oxide (HfOX), hafnium silicon oxide (HfSiO₄), hafnium silicon oxynitride (HfSiON), aluminum oxide (alumina), Al₂O₃), tantalum oxide (Ta₂O₅), zirconium oxide (ZrO₂) or other suitable high dielectric constant materials. Therefore, the material composition of the gate dielectric layer 34 may be the same as or different from that of the first oxide layer 30 and the second oxide layer 32, and the thickness of the gate dielectric layer 34 may be smaller than that of the first oxide layer 30 and the second oxide layer 32. In addition, in some embodiments, both sides of the gate electrode GE may include spacers (not shown), which may include a single layer or multiple layers of dielectric materials, such as silicon oxide, silicon nitride, silicon oxynitride or other suitable dielectric materials.

The gate electrode GE, the gate dielectric layer 34, the first oxide layer 30, the second oxide layer 32, the field plate 40, the source doped region SR, the drain doped region DR and the drift region 26 can form a high-voltage semiconductor device, and the high-voltage semiconductor device can include a double-diffused MOS (DMOS) device, for example, a DMOS device in a Bipolar-CMOS-DMOS (BCD) structure, but not limited thereto.

In some embodiments, by arranging the first oxide layer 30, the second oxide layer 32 and the field plate 40, and electrically connecting the field plate 40 with the gate electrode GE, the on-resistance of the semiconductor device 101 can be reduced, and the second oxide layer 32 can be used to enhance the effect of reducing the on-resistance or/and improving the breakdown voltage of the semiconductor device 101. The intensity of the electric field generated by the semiconductor device 101 on the surface of the substrate 10 can be reduced and the electric field distribution can be made uniform, thereby improving the related electrical performance of the semiconductor device 101.

The following description will detail the different embodiments of the device and the manufacturing method of the present invention. To simplify the description, the following description will detail the dissimilarities among the different embodiments and the identical features will not be redundantly described. In order to compare the differences between the embodiments easily, the identical components in each of the following embodiments are marked with identical symbols.

In the above embodiment, after the first oxide layer 30 is formed, the second oxide layer 32 and the field plate 40 are formed over the first oxide layer 30. However, there is still a space for further simplification of such steps. In the following second embodiment, a semiconductor device with the same effect of homogenizing electric field distribution and simpler manufacturing steps is provided.

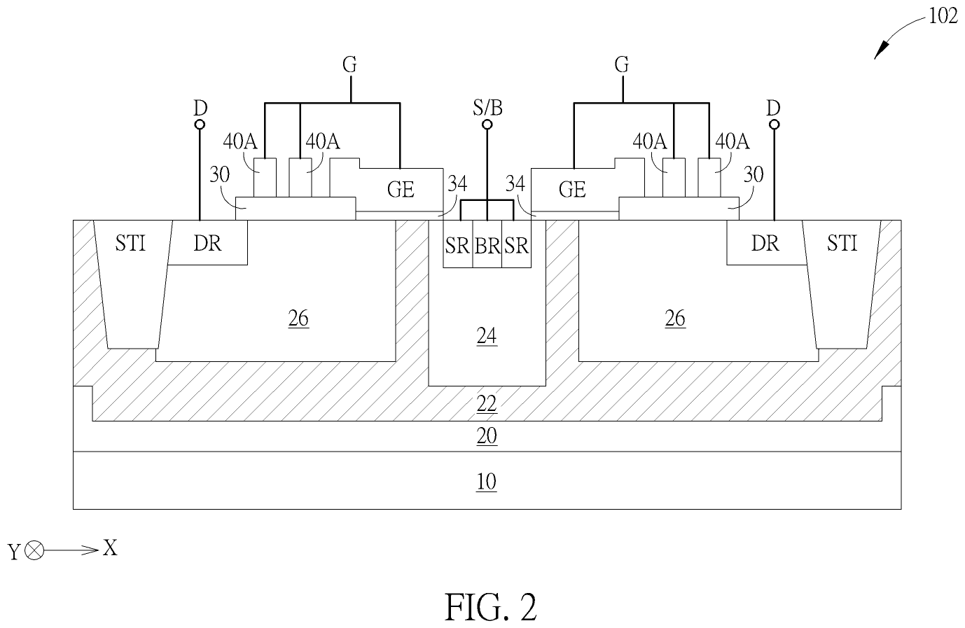

Please refer to FIG. 2, which provides a semiconductor device 102, wherein most of the semiconductor devices 102 are the same as or similar to the semiconductor device 101 described in the first embodiment, including a substrate 10, a deep well region 20, a deep well region 22, a doped well region 24, a drift region 26, a gate electrode GE, a source doped region SR, a drain doped region DR, a body doped region BR, a first oxide layer 30, a gate dielectric layer 34 and shallow trench isolation STI, these elements are denoted by the same reference numerals, which means that these elements have the same structure as those described in the first embodiment, so they are not repeated here. The main difference between this embodiment and the first embodiment is that in order to save steps, the process steps of forming the second oxide layer 32 and the field plate 40 in the first embodiment are omitted, and the photomask pattern of the gate electrode GE is changed. At the same time of forming the gate electrode GE, the field plate 40A is simultaneously formed on the first oxide layer 30 in the same photolithography step by using the same photomask. Since the field plate 40A is formed at the same time as the gate electrode GE, the material of the field plate 40A is the same as that of the gate electrode GE, and the field plate 40A is located on and directly contacts the first oxide layer 30. In addition, since the field plate 40A in this embodiment is not formed on the second oxide layer 32, so the top surface of the field plate 40A in this embodiment is aligned with the top surface of a part of the gate electrode GE.

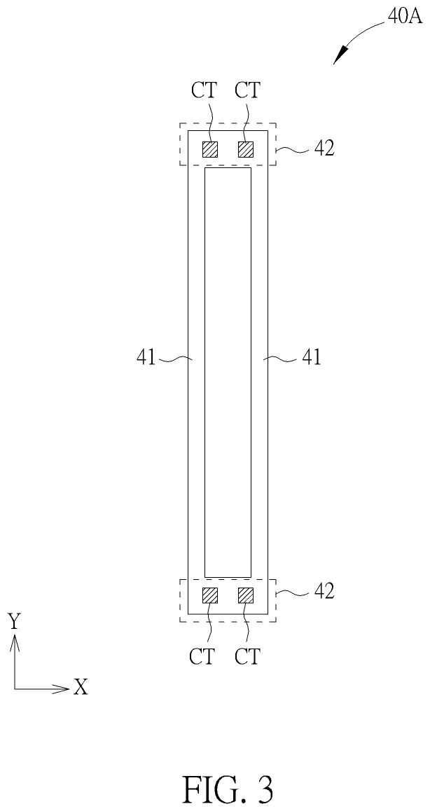

Please refer to FIG. 3, which is a schematic top view of the field plate according to the second embodiment of the present invention. In order to clearly illustrate the features of the present invention, only the shape of the field plate 40A is described in FIG. 3, and other surrounding elements are omitted. Seen from the top view, in this embodiment, the field plate 40A has a rectangular frame shape, specifically, it has long-side portions 41 arranged along the Y direction and short-side portions 42 extending along the X direction, wherein the length of the long-side portion 41 is longer than the length of the short-side portion 42, and the width of the long-side portion 41 is smaller than the width of the short-side portion 42, that is to say, the long-side portion 41 is a more slender pattern than the short-side portion 42. In addition, a contact structure CT is further included to be electrically connected with the field plate 40A. Because the width of the short-side portion 42 is large, the contact structure CT is preferably formed on the short-side portion 42, which is easier to align and electrically connect with the field plate 40A. The contact structure CT is used to electrically connect the field plate 40A to other elements, for example, it can be electrically connected to the gate electrode GE through other metal layers. Therefore, as shown in FIG. 2, by electrically connecting the field plate 40A with the gate electrode GE, the effect of dispersing the electric field as that of the semiconductor device 101 described in the first embodiment can also be achieved in this embodiment, thereby improving the yield of the semiconductor device, and the manufacturing process of the semiconductor device 102 in this embodiment is simpler than that of the semiconductor device 101 described in the first embodiment.

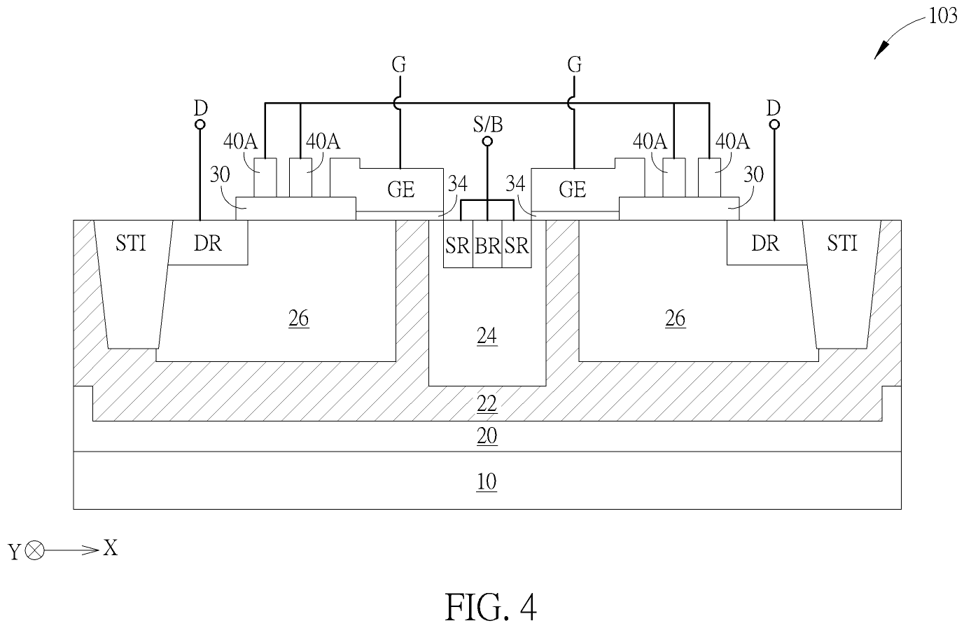

FIG. 4 is a schematic cross-sectional view of a semiconductor device according to a third embodiment of the present invention. As shown in FIG. 4, a semiconductor device 103 is provided. Most of the elements in this embodiment are the same as those in the second embodiment, and the same elements are denoted by the same reference numerals and will not be repeated. This embodiment is different from the above-mentioned second embodiment in that the field plate 40A is not connected to the gate electrode GE, but to the source terminal S. In this way, the gate-drain capacitance (Cgd) can be improved to reduce the gate charge of the semiconductor device 103, that is, the gate capacitance can be reduced and the quality of the semiconductor device can be improved. On the other hand, the semiconductor device 103 of this embodiment also has the same advantages as the semiconductor device 102 described in the second embodiment, such as simplifying the manufacturing process. In addition, since the field plate 40A has a single-layer structure, when a dielectric layer (not shown) is subsequently formed to cover the field plate 40A, the uniformity and flatness of the dielectric layer are better, which are all advantages of this embodiment.

In addition, in other embodiments of the present invention, the field plate 40A can also be connected to the drain terminal D (not shown) as required, and this variation is also within the scope of the present invention.

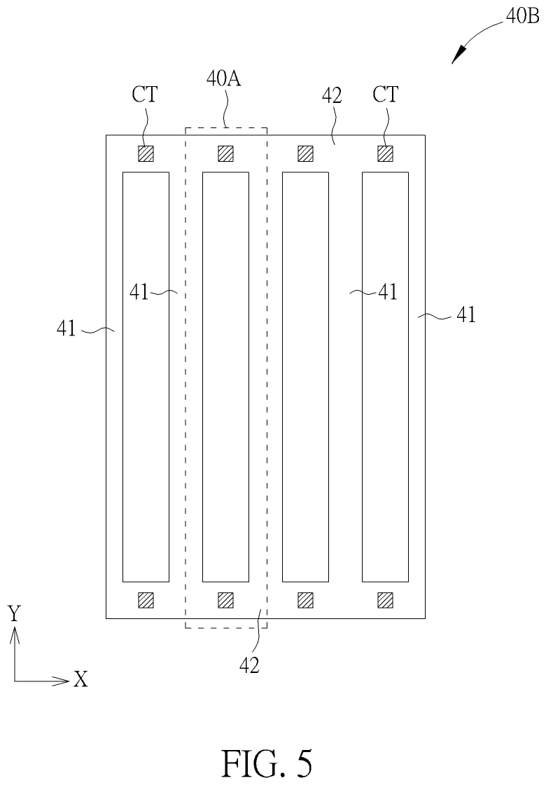

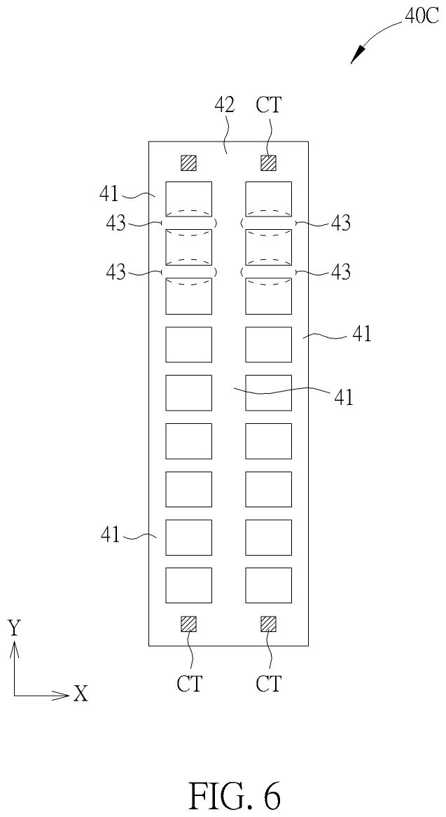

In the above embodiment, the field plate 40A has a rectangular frame shape when viewed from the top, but in other embodiments of the present invention, the field plate 40A may have other shapes. For example, please refer to FIG. 5 and FIG. 6. FIGS. 5 and 6 respectively show schematic top views of two other different embodiments of the field plate of the present invention. As shown in FIG. 5, in one embodiment, a field plate 40B is provided, wherein the field plate 40B presents a fence shape when viewed from a top view. Among them, the field plate 40B can also be regarded as repeating the rectangular frame shape field plate 40A shown in FIG. 3. The field plate 40B also includes a plurality of long-side portions 41 and a plurality of short-side portions 42, and the contact structure CT is located on the short-side portions 42. These elements are the same as or similar to those shown in FIG. 3 above, and will not be repeated here.

In addition, in other embodiments, the size of the long rectangular field plates 40A can be adjusted. For example, in FIG. 5, it can be seen that four long rectangular field plates 40A are formed side by side, and the size of each long rectangular field plate 40A is approximately the same as each other. However, in other embodiments of the present invention, the size of each rectangular field plate 40A can be adjusted. For example, it is possible that the distance between two long-side portions 41 in some rectangular field plates 40A is relatively short, while the distance between two long-side portions 41 in another rectangular field plate 40A is relatively long. This variation is also within the scope of the present invention.

As shown in FIG. 6, in one embodiment, a field plate 40C is provided, in which the field plate 40C presents a mesh shape when viewed from a top view. The field plate 40C can also be regarded as inserting a plurality of connecting portions 43 into the rectangular frame shape field plate 40A shown in FIG. 3, wherein the connecting portions 43 connect two adjacent long-side portions 41 and are perpendicular to the extending direction of the long-side portions 41. For example, in this embodiment, the long-side portion 41 extends along the Y direction, so the connecting portion 43 extends along the X direction. In this embodiment, the function of forming the connecting portion 43 is to strengthen the structure of the field plate 40C and avoid the collapse of the field plate structure. More specifically, because the long-side portion 41 is a slender pattern, its aspect ratio is large (for example, when the length is about 50 microns, the width is only 0.09 microns). When forming the long-side portion 41, the pattern is easy to collapse due to the large aspect ratio. At this time, forming the connecting portion 43 can strengthen the structure of the field plate 40C and avoid the collapse phenomenon.

Based on the above description and drawings, the present invention provides a semiconductor device 102, which comprises a substrate 10, a first oxide layer 30 located on a surface of the substrate 10, a gate electrode GE located on the substrate 10 and partially contacting the substrate 10, part of the gate electrode GE located on the first oxide layer 30, and a field plate 40A located on the first oxide layer 30, wherein the field plate 30 has at least one rectangular frame shape when viewed from a top view.

In some embodiments of the present invention, a doped well region 24 is located in the substrate 10, and a source terminal S is electrically connected to the doped well region 24.

In some embodiments of the present invention, a drift region 26 and a drain doped region DR are located in the substrate, wherein part of the gate electrode GE and the first oxide layer 30 are located on the drift region 26.

In some embodiments of the present invention, it further includes a drain terminal D electrically connected to the drain doped region DR.

In some embodiments of the present invention, the doped well region 24 has a first conductivity type (e.g., P type), and the drift region 26 and the drain doped region DR have a second conductivity type (e.g., N type), and the first conductivity type is complementary to the second conductivity type.

In some embodiments of the present invention, the field plate 40A is electrically connected to the gate electrode GE (such as the embodiment shown in FIG. 2).

In some embodiments of the present invention, the field plate 40B is electrically connected to the source terminal S (such as the embodiment shown in FIG. 4).

In some embodiments of the present invention, when viewed from the top, the field plate presents a rectangular frame shape, and the rectangular frame shape includes two long-side portions 41 and two short-side portions 42.

In some embodiments of the present invention, a plurality of contact structures CT are further included, which are located on two short-side portions 42 of the field plate 40A.

In some embodiments of the present invention, a plurality of connecting portions 43 are arranged between the two long-side portions 41 of the field plate 40C, and each connecting portion 43 directly contacts the two long-side portions 41 of the field plate 40C (as in the embodiment shown in FIG. 6).

In some embodiments of the present invention, the connecting portions 43 and the field plate 40C have the same material, and when viewed from the top, each connecting portion 43 and the field plate 40C together form a net shape.

In some embodiments of the present invention, a top surface of the field plate 40A is aligned with a top surface of the gate electrode GE when viewed from a cross section.

The invention further provides a method for forming a semiconductor device, which comprises providing a substrate, forming a first oxide layer 30 on a surface of the substrate 10, forming a gate electrode GE on the substrate 10 and partially contacting the substrate 10, part of the gate electrode GE located on the first oxide layer 30, and forming a field plate 40A on the first oxide layer 30, wherein the field plate 40A has at least a rectangular frame shape when viewed from a top view.

In some embodiments of the present invention, a doped well region 24, a drift region 26 and a drain doped region DR are formed in the substrate.

In some embodiments of the present invention, it further includes forming a source terminal S electrically connected to the doped well region 24, and forming a drain terminal D electrically connected to the doped drain region DR.

In some embodiments of the present invention, the field plate 40 is electrically connected to the source terminal S, the gate electrode GE or the drain terminal D.

In some embodiments of the present invention, the gate electrode GE and the first oxide layer 30 are located on the drift region 26.

In some embodiments of the present invention, the field plate 40A is formed at the same time as the gate electrode GE.

In some embodiments of the present invention, the field plate 40A has a rectangular frame shape when viewed from the top, and the rectangular frame shape includes two long-side portions 41 and two short-side portions 42.

In some embodiments of the present invention, a plurality of connecting portions 43 are formed, which are arranged between the two long-side portions 41 of the field plate 40C, and each connecting portion 43 directly contacts the two long-side portions 41 of the field plate 40C, and when viewed from the top, each connecting portion 43 and the field plate 40C together form a net shape (refer to the embodiment of FIG. 6).

The invention is characterized by providing a semiconductor device with a filed plate, in particular to a lateral double-diffused metal-oxide-semiconductor (LDMOS) transistor device with a field plate with a special shape. In which, from the top view, the field plate presents a long rectangular frame shape or a net shape, while from the cross-sectional view, the field plate directly contacts the first oxide layer. The semiconductor device of the invention not only has the effect of dispersing electric field, but also has the advantages of simple process and stable structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device comprising:
a substrate;
a first oxide layer located on a surface of the substrate;
a gate electrode located on the substrate and partially contacting the substrate, and part of the gate electrode located on the first oxide layer; and
a field plate located on the first oxide layer, wherein the field plate has at least a rectangular frame shape when viewed from a top view.

2. The semiconductor device according to claim 1, further comprising a doped well region in the substrate, and a source terminal is electrically connected to the doped well region.

3. The semiconductor device according to claim 2, further comprising a drift region and a drain doped region located in the substrate, wherein part of the gate electrode and the first oxide layer are located on the drift region.

4. The semiconductor device according to claim 3, further comprising a drain terminal electrically connected to the drain doped region.

5. The semiconductor device according to claim 3, wherein the doped well region has a first conductivity type, and the drift region and the drain doped region have a second conductivity type, and the first conductivity type is complementary to the second conductivity type.

6. The semiconductor device according to claim 1, wherein the field plate is electrically connected to the gate electrode.

7. The semiconductor device according to claim 2, wherein the field plate is electrically connected to the source terminal.

8. The semiconductor device according to claim 1, wherein the field plate has a rectangular frame shape when viewed from the top view, and the rectangular frame shape includes two long-side portions and two short-side portions.

9. The semiconductor device according to claim 8, further comprising a plurality of contact structures located on the two short-side portions of the field plate.

10. The semiconductor device according to claim 8, further comprising a plurality of connecting portions arranged between the two long-side portions of the field plate, and each connecting portion directly contacts the two long-side portions of the field plate.

11. The semiconductor device according to claim 10, wherein the connecting portions are made of the same material as the field plate, and when viewed from the top, each connecting portion and the field plate constitute a net shape.

12. The semiconductor device according to claim 1, wherein a top surface of the field plate is flush with a top surface of the gate electrode when viewed from a cross section.

13. A method for forming a semiconductor device, comprising:
providing a substrate;
forming a first oxide layer on a surface of the substrate;
forming a gate electrode on the substrate, the gate electrode partially contacts the substrate, and part of the gate electrode located on the first oxide layer; and
forming a field plate on the first oxide layer, wherein the field plate has at least a rectangular frame shape when viewed from a top view.

14. The method for forming a semiconductor device according to claim 13, further comprising forming a doped well region, a drift region and a drain doped region in the substrate.

15. The method for forming a semiconductor device according to claim 14, further comprising forming a source terminal electrically connected to the doped well region and forming a drain terminal electrically connected to the doped drain region.

16. The method for forming a semiconductor device according to claim 15, wherein the field plate is electrically connected to the source terminal, the gate electrode or the drain terminal.

17. The method for forming a semiconductor device according to claim 14, wherein the gate electrode and the first oxide layer are located on the drift region.

18. The method for forming a semiconductor device according to claim 13, wherein the field plate and the gate electrode are formed at the same time.

19. The method for forming a semiconductor device according to claim 13, wherein the field plate has a rectangular frame shape when viewed from the top view, and the rectangular frame shape includes two long-side portions and two short-side portions.

20. The method for forming a semiconductor device according to claim 19, further comprising forming a plurality of connecting portions arranged between the two long-side portions of the field plate, and each connecting portion directly contacts the two long-side portions of the field plate, and when viewed from the top, each connecting portion and the field plate constitute a net shape.
